(19) United States
(12) Patent Application Publication
(10) Pub. No.: US 2005/0233259 A1
(43) Pub. Date: Oct. 20, 2005

(54) Resist material and pattern formation method using the same

(75) Inventors: Masayuki Endo, Osaka (JP); Masaru Sasago, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/071,163

(22) Filed: Mar. 4, 2005

(30) Foreign Application Priority Data
Apr. 2, 2004 (JP) 2004-109633

(51) Int. Cl. G03F 7/00

(52) U.S. Cl. 430/313; 430/270.1; 430/296

(57) ABSTRACT

After forming a resist film including titanium oxide on a substrate, pattern exposure is performed by selectively irradiating the resist film with light of a wavelength of 400 nm or less or an electron beam. After the pattern exposure, the resist film is developed, so as to form a resist pattern made of the resist film.

### CROSS-REFERENCE TO RELATED APLICATIONS

This application claims priority under 35 U.S.C. §119 on Patent Application No. 2004-109633 filed in Japan on Apr. 2, 2004, the entire contents of which are hereby incorporated by reference.

### BACKGROUND OF THE INVENTION

The present invention relates to a resist material for use in fabrication process or the like for semiconductor devices and a pattern formation method using the same.

In accordance with the increased degree of integration of semiconductor integrated circuits and downsizing of semiconductor devices, there are increasing demands for further higher performance of lithography technique. In particular, in order to refine a pattern, higher and higher performance is required of a resist material. Therefore, currently, a chemically amplified resist is frequently used as a resist material for obtaining a fine pattern. In a chemical amplified resist, an acid is generated from an acid generator included therein through exposure and post exposure bake, and the thus generated acid is used as a catalyst for causing a reaction of the resist. Therefore, the resolution and the sensitivity of the resist can be improved by using the chemically amplified resist.

Now, a conventional pattern formation method using a chemically amplified resist will be described with reference to FIGS. 7A through 7D.

First, a positive chemically amplified resist material having the following composition is prepared:

| | | |
|---|---|---|
| Base polymer: poly((t-butyloxycarbonylmethyloxystyrene) | 2 | g |
| (35 mol %) - (hydroxystyrene) (65 mol %)) | | |
| Acid generator: triphenylsulfonium nonaflate | 0.05 | g |
| Quencher: triethanolamine | 0.002 | g |
| Solvent: propylene glycol monomethyl ether acetate | 18 | g |

Next, as shown in FIG. 7A, the aforementioned chemically amplified resist material is applied on a substrate 1 so as to form a resist film 2 with a thickness of 0.4 μm.

Then, as shown in FIG. 7B, pattern exposure is carried out by irradiating the resist film 2 with exposing light 3 of KrF excimer laser with NA of 0.68 through a mask 4.

After the pattern exposure, as shown in FIG. 7C, the resist film 2 is baked with a hot plate at a temperature of 105° C. for 60 seconds (post exposure bake).

Next, the resultant resist film 2 is developed with a 2.38 wt % tetramethylammonium hydroxide developer 5. In this manner, a resist pattern 2a made of an unexposed portion of the resist film 2 and having a line width of 0.13 μm is formed as shown in FIG. 7D.

However, the resist pattern 2a formed by the conventional pattern formation method is in a defective shape with a lower portion thereof not resolved as shown in FIG. 7D. Thus, even when a chemically amplified resist is used, the resolution of the resist is not sufficiently high. When the resist pattern 2a in such a defective shape is used for etching a target film, the resultant pattern of the target film is also in a defective shape, which disadvantageously lowers the productivity and the yield in the fabrication process for semiconductor devices.

### SUMMARY OF THE INVENTION

In consideration of the aforementioned conventional disadvantage, an object of the invention is forming a fine pattern in a good shape by improving the resolution (i.e., a dissolution contrast) of a resist film.

The present inventors have variously studied for improving the dissolution contrast of a resist film, resulting in finding the following: When titanium oxide is irradiated with light of a wavelength of 400 nm or less or an electron beam, the titanium oxide attains a hydrophilic property. Therefore, when titanium oxide is included in a resist, an exposed portion of a resist film, which generally attains a hydrophilic property through a photoreaction of an acid generator or a photoreaction reagent, becomes more hydrophilic but an unexposed portion remains to be hydrophobic. Accordingly, a larger difference is caused between the polarities corresponding to the hydrophilic property of the exposed portion and the hydrophobic property of the unexposed portion of the resist film including the titanium oxide. When the difference between the polarities of the exposed portion and the unexposed portion of the resist film is thus increased, a dissolution contrast, that is, a difference in the dissolution rate between the exposed portion and the unexposed portion of the resist film attained in development, is increased, resulting in improving the resolution of the resist film and the shape of a resultant pattern.

It is described by R. Wang et al., in Nature, vol. 388, p. 431 (1997) that titanium oxide attains a hydrophilic property through irradiation with UV. According to this article, titanium oxide irradiated with UV attains a hydrophilic property for the following reason: Electrons and holes are generated in titanium oxide through irradiation with UV, and the generated electrons and holes are respectively bonded to oxygen and water molecules included in the air, so as to form active oxygen species (such as superoxide anions and OH radicals). These active oxygen species exhibit a hydrophilic property.

Also, in dry etching using an etching gas of an oxygen-based gas, the resist including titanium oxide has etch resistance with respect to an organic film. Therefore, when an organic film is etched by using a resist pattern including titanium oxide as a mask, a multilayered pattern having a two-layer structure can be formed. Furthermore, an inorganic film may be deposited between a resist film including titanium oxide and an organic film, and in this case, a multilayered pattern having a three-layer structure, in which the inorganic film reinforces (compensates) the oxygen-based etch resistance of titanium oxide with respect to the organic film, can be formed.

The content of the titanium oxide in the resist is appropriately not more than 0.1 wt % and not less than 10 wt %, which does not limit the invention. Also, the particle size of the titanium oxide may be a nano particles size, and the titanium oxide exhibits a hydrophilic property through exposure with light of a wavelength of 400 nm or less or an electron beam.

The present invention was devised on the basis of the aforementioned findings, and according to the invention, titanium oxide is included in a resist film, so as to improve a dissolution contrast by improving the hydrophilic property of an exposed portion of the resist film. Specifically, the present invention is practiced as follows:

The resist material of this invention includes titanium oxide.

Since the resist material of this invention includes titanium oxide, an exposed portion, which attains a hydrophilic property through, for example, a photoreaction of an acid generator or a photoreaction reagent, becomes more hydrophilic but an unexposed portion remains to be hydrophobic. Therefore, a difference in the polarity between the exposed portion and the unexposed portion of the resist becomes large. When the difference in the polarity between the exposed portion and the unexposed portion becomes large, a dissolution contrast obtained in development is increased. As a result, the resolution of the resist is improved, so that a resist pattern can be formed in a good shape.

The first pattern formation method of this invention includes the steps of forming a resist film including titanium oxide on a substrate; performing pattern exposure by selectively irradiating the resist film with light of a wavelength of 400 nm or less or an electron beam; and forming a resist pattern made of the resist film by developing the resist film after the pattern exposure.

In the first pattern formation method, the resist film including titanium oxide becomes more hydrophilic in an exposed portion but an unexposed portion thereof remains to be hydrophobic. Therefore, a difference in the polarity between the exposed portion and the unexposed portion becomes large, and hence, a dissolution contrast obtained in development is increased. As a result, the resolution of the resist film is improved, so that the resist pattern can be formed in a good shape.

The second pattern formation method of this invention includes the steps of forming an organic film on a substrate; forming a first resist film including titanium oxide on the organic film; performing pattern exposure by selectively irradiating the first resist film with light of a wavelength of 400 nm or less or an electron beam; forming a resist pattern made of the first resist film by developing the first resist film after the pattern exposure; and forming a pattern by etching the organic film with the resist pattern used as a mask.

In the second pattern formation method, the first resist film including titanium oxide becomes more hydrophilic in an exposed portion but an unexposed portion thereof remains to be hydrophobic. Therefore, a difference in the polarity between the exposed portion and the unexposed portion of the first resist film becomes large, and hence, a dissolution contrast obtained in development is increased. As a result, the resolution of the first resist film is improved, so that the resist pattern can be formed in a good shape. In addition, since the first resist film including titanium oxide has high etch resistance in an oxidizing atmosphere, the resist pattern made of the first resist film can be used as a mask for etching the organic film provided below with oxygen plasma. As a result, a multilayered pattern composed of the resist pattern and the organic film can be formed in a good shape.

The second pattern formation method preferably further includes, between the step of forming an organic film and the step of forming a first resist film, a step of forming an inorganic film on the organic film, and the pattern is preferably formed by etching the inorganic film and the organic film with the resist pattern used as a mask in the step of forming a pattern. Thus, since the inorganic film has high resistance against oxygen plasma, when the inorganic film and the organic film are etched by using the resist pattern as a mask for forming a pattern including the organic film, the inorganic film reinforces (compensates) the resist pattern.

In the first pattern formation method, the resist film is preferably made of a chemically amplified resist.

In the second pattern formation method, the first resist film is preferably made of a chemically amplified resist.

In the second pattern formation method, it is preferred in the step of forming an organic film that a second resist film is formed on the substrate and that the second resist film is subjected to hard bake. Thus, the organic film can be easily and definitely formed. It is noted that the organic film is not limited to a hard baked resist film but may be made of a hydrocarbon film, a carbon film or the like.

In this case, the hard bake is preferably performed at a temperature of 200° C. or more.

In the second pattern formation method, in the case where the inorganic film is used, the inorganic film may be made of silicon oxide, silicon nitride or silicon oxide nitride.

In the first or second pattern formation method, the light of a wavelength of 400 nm or less is preferably i-line, KrF excimer laser, ArF excimer laser, F₂ laser, ArKr laser, Ar₂ laser or extreme UV of a wavelength not shorter than 1 nm and not longer than 30 nm. Thus, the titanium oxide included in the resist can be definitely made hydrophilic.

### BRIEF DESCRIPTION OF THE DRAWINGS

FIGS. 1A, 1B, 1C and 1D are cross-sectional views for showing procedures in a pattern formation method according to Embodiment 1 of the invention;

FIGS. 2A, 2B, 2C and 2D are cross-sectional views for showing procedures in a pattern formation method according to Embodiment 2 of the invention;

FIGS. 3A, 3B and 3C are cross-sectional views for showing other procedures in the pattern formation method according to Embodiment 2 of the invention;

FIGS. 4A, 4B, 4C and 4D are cross-sectional views for showing procedures in a pattern formation method according to Embodiment 3 of the invention;

FIGS. 5A, 5B, 5C and 5D are cross-sectional views for showing other procedures in the pattern formation method according to Embodiment 3 of the invention;

FIGS. 6A and 6B are cross-sectional views for showing other procedures in the pattern formation method according to Embodiment 3 of the invention; and

FIGS. 7A, 7B, 7C and 7D are cross-sectional views for showing procedures in a conventional pattern formation method using a chemically amplified resist.

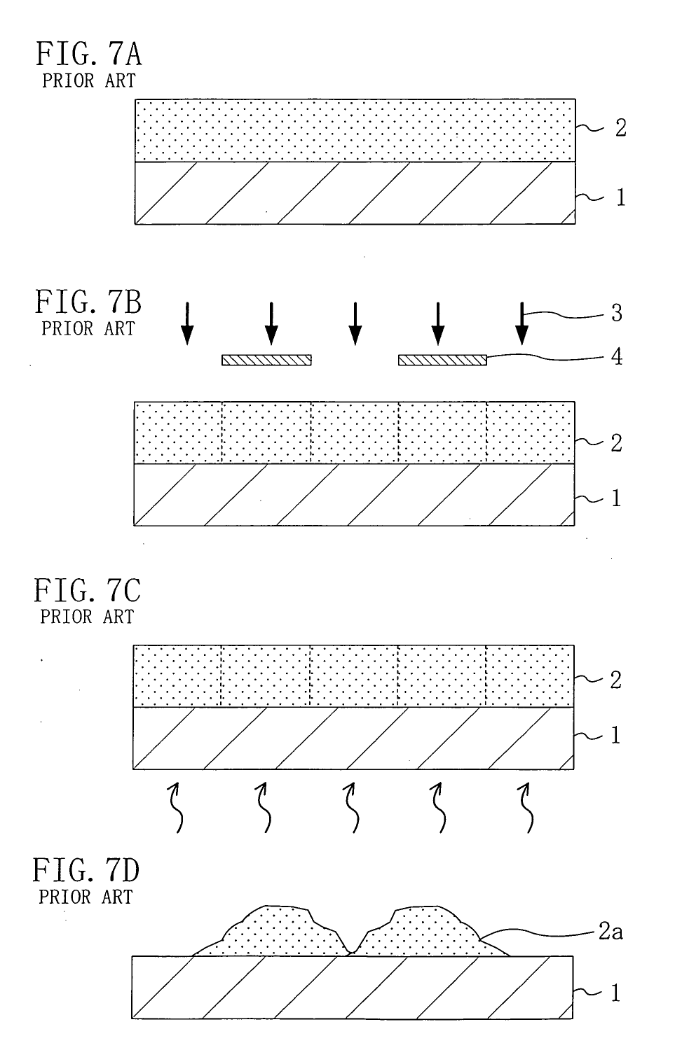

### DETAILED DESCRIPTION OF THE INVENTION

### Embodiment 1

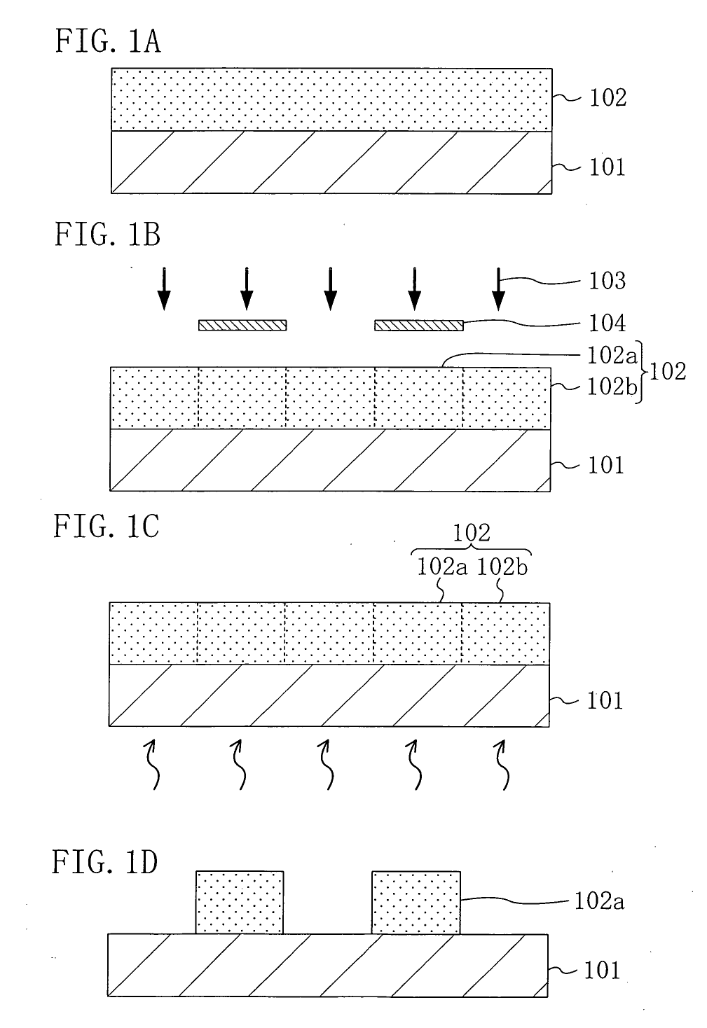

A pattern formation method according to Embodiment 1 of the invention will now be described with reference to FIGS. 1A through 1D.

First, a positive chemically amplified resist material having the following composition used for forming a first resist film is prepared:

| | | |
|---|---|---|
| Base polymer: poly((t-butyloxycarbonylmethyloxystyrene) | 2 | g |
| (35 mol %) - (hydroxystyrene) (65 mol %)) | | |
| Resolution potentiator: titanium oxide | 0.2 | g |
| Acid generator: triphenylsulfonium nonaflate | 0.05 | g |
| Quencher: triethanolamine | 0.002 | g |
| Solvent: propylene glycol monomethyl ether acetate | 18 | g |

Next, as shown in FIG. 1A, the aforementioned chemically amplified resist material is applied on a substrate 101 so as to form a resist film 102 with a thickness of 0.4 μm.

Then, as shown in FIG. 1B, pattern exposure is carried out by irradiating the resist film 102 with exposing light 103 of KrF excimer laser with NA of 0.68 through a mask 104.

After the pattern exposure, as shown in FIG. 1C, the resist film 102 is baked with a hot plate at a temperature of 105° C. for 60 seconds (post exposure bake).

Next, as shown in FIG. 1D, the resultant resist film 102 is developed with a 2.38 wt % tetramethylammonium hydroxide aqueous solution (alkaline developer). In this manner, a resist pattern 102a made of an unexposed portion of the resist film 102 and having a line width of 0.13 μm is formed in a good shape as shown in FIG. 1D.

In this manner, according to Embodiment 1, in the resist film 102 including titanium oxide, the titanium oxide included in an exposed portion 102b becomes hydrophilic in the exposure shown in FIG. 1B, and hence, the exposed portion 102b, which attains a hydrophilic property through a photoreaction of the acid generator, becomes more hydrophilic. On the contrary, the unexposed portion of the resist film 102 keeps its hydrophobic property. Therefore, in the development shown in FIG. 1D, a dissolution contrast, that is, a difference in the dissolution rate between the exposed portion 102b and the unexposed portion, is increased. As a result, the resolution of the resist film 102 is improved, so that the resist pattern 102a can be formed in a good shape.

### Embodiment 2

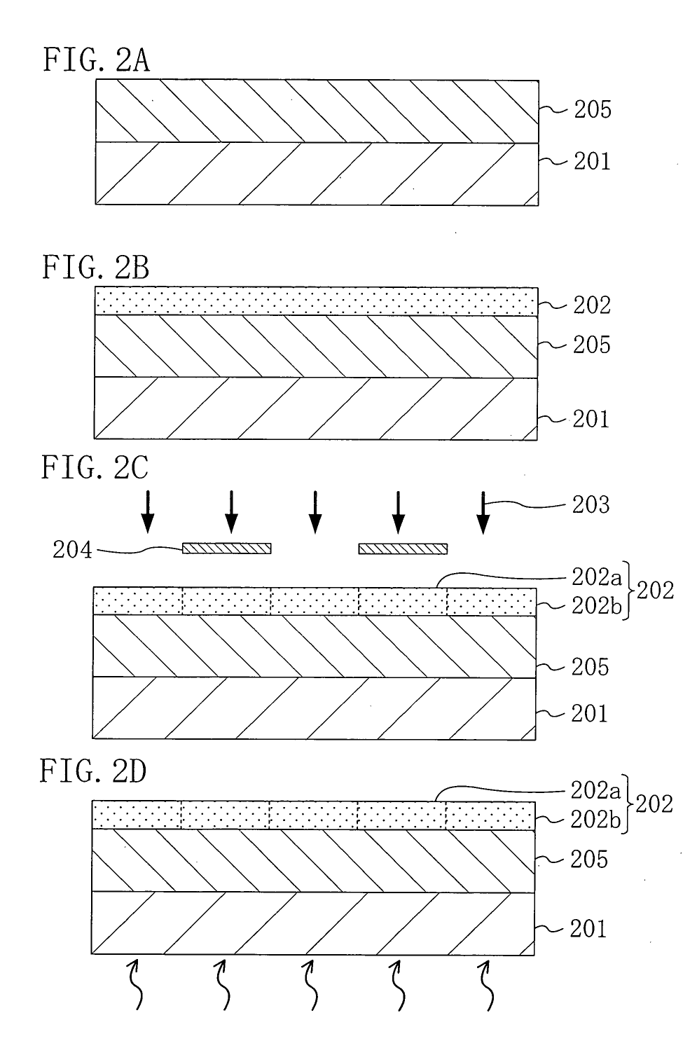

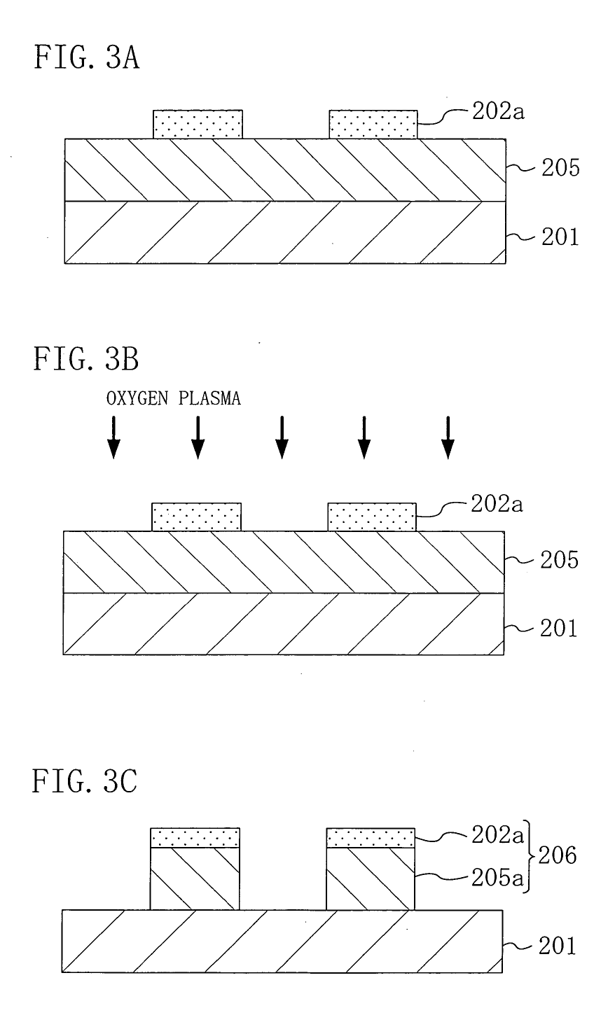

A pattern formation method according to Embodiment 2 of the invention will now be described with reference to FIGS. 2A through 2D and 3A through 3C.

First, a resist material for forming an organic film having the following composition is prepared:

| | | |
|---|---|---|
| Base polymer: novolak resin | 3 | g |
| 1,2,3-trihydroxybenzophenone-5-diazonaphthoquinone sulfonate | 0.9 | g |
| Solvent: cyclohexanone | 15 | g |

Next, as shown in FIG. 2A, the resist material is applied on a substrate 201, and the applied resist material is baked at a temperature of 250° C. for 180 seconds, so as to form an organic film 205 with a thickness of 0.4 μm. Herein, a resist film obtained before the hard bake corresponds to a second resist film.

Then, a positive chemically amplified resist material having the following composition used for forming a first resist film is applied on the organic film 205 so as to form a resist film 202 with a thickness of 0.2 μm:

| | | |
|---|---|---|
| Base polymer: poly((t-butyloxycarbonylmethyloxystyrene) | 1.2 | g |
| (35 mol %) - (hydroxystyrene) (65 mol %)) | | |
| Resolution potentiator: titanium oxide | 0.2 | g |
| Acid generator: triphenylsulfonium nonaflate | 0.04 | g |
| Quencher: triethanolamine | 0.002 | g |
| Solvent: propylene glycol monomethyl ether acetate | 18 | g |

Then, as shown in FIG. 2C, pattern exposure is carried out by irradiating the resist film 202 with exposing light 203 of KrF excimer laser with NA of 0.68 through a mask 204.

After the pattern exposure, as shown in FIG. 2D, the resist film 202 is baked with a hot plate at a temperature of 110° C. for 60 seconds (post exposure bake).

Next, the resultant resist film 202 is developed with a 2.38 wt % tetramethylammonium hydroxide aqueous solution (alkaline developer). In this manner, a resist pattern 202a made of an unexposed portion of the resist film 202 and having a line width of 0.13 μm is formed in a good shape as shown in FIG. 3A.

Subsequently, as shown in FIG. 3B, the organic film 205 is etched by using oxygen plasma with the resist pattern 202a used as a mask, so as to obtain a multilayered pattern 206 with a line width of 0.13 μm having a two-layered structure in a good shape composed of the resist pattern 202a and an organic film pattern 205a below as shown in FIG. 3C.

In this manner, according to Embodiment 2, in the resist film 202 including titanium oxide, the titanium oxide included in an exposed portion 202b becomes hydrophilic in the exposure shown in FIG. 2C, and hence, the exposed portion 202b, which attains a hydrophilic property through a photoreaction of the acid generator, becomes more hydrophilic. On the contrary, the unexposed portion of the resist film 202 keeps its hydrophobic property. Therefore, in the development shown in FIG. 3A, a dissolution contrast, that is, a difference in the dissolution rate between the exposed portion 202b and the unexposed portion, is increased. As a result, the resolution of the resist film 202 is improved, so that the resist pattern 202a can be formed in a good shape.

Furthermore, in the dry etching using oxygen plasma shown in FIG. 3B, since the resist pattern 202a exhibits sufficient etch resistance owing to the titanium oxide included therein, the resultant multilayered pattern 206 is in a good shape.

It is noted that the organic film 205 is not limited to a hard baked resist film but may be made of hydrocarbon, carbon or the like.

### Embodiment 3

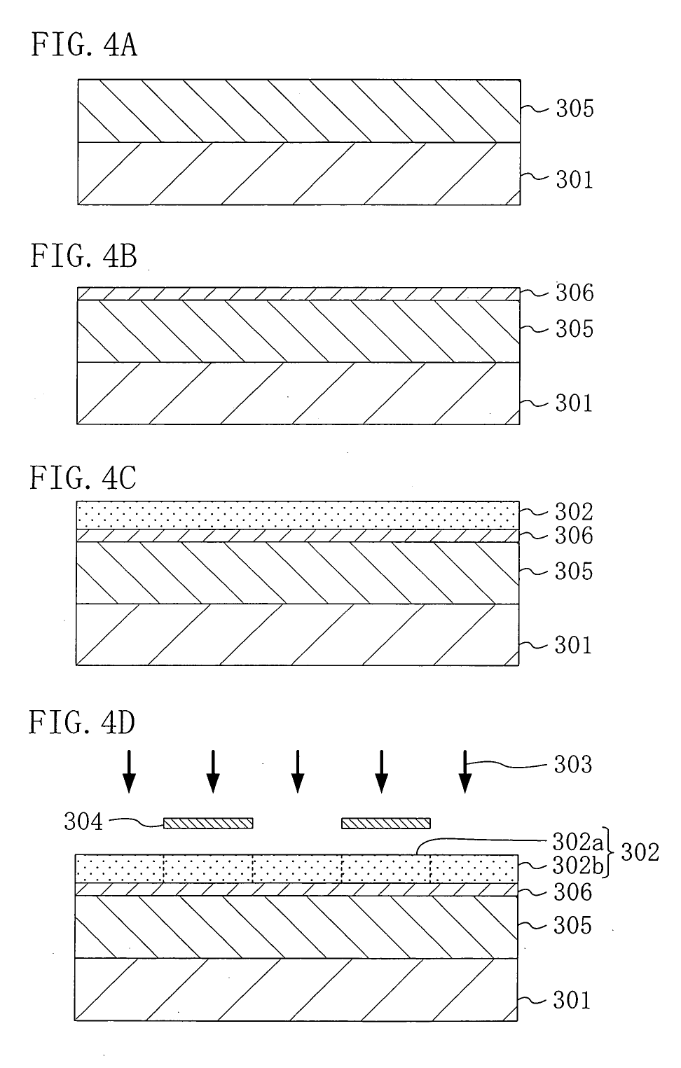

A pattern formation method according to Embodiment 3 of the invention will now be described with reference to FIGS. 4A through 4D, 5A through 5D and 6A through 6C.

First, a resist material for forming an organic film having the following composition is prepared:

| | | |
|---|---|---|
| Base polymer: novolak resin | 3 | g |
| 1,2,3-trihydroxybenzophenone-5-diazonaphthoquinone sulfonate | 0.9 | g |
| Solvent: cyclohexanone | 15 | g |

Next, as shown in FIG. 4A, the resist material is applied on a substrate 301, and the applied resist material is baked at a temperature of 250° C. for 180 seconds, so as to form an organic film 305 with a thickness of 0.4 μm.

Then, as shown in FIG. 4B, an inorganic film 306 made of silicon oxide nitride (SiON) with a thickness of 0.1 μm is formed on the organic film 305 by, for example, chemical vapor deposition (CVD).

Next, as shown in FIG. 4C, a positive chemically amplified resist material having the following composition is applied on the inorganic film 306 so as to form a resist film 302 with a thickness of 0.2 μm:

| | | |
|---|---|---|
| Base polymer: poly((t-butyloxycarbonylmethyloxystyrene) | 1.2 | g |
| (35 mol %) - (hydroxystyrene) (65 mol %)) | | |
| Resolution potentiator: titanium oxide | 0.1 | g |
| Acid generator: triphenylsulfonium nonaflate | 0.04 | g |
| Quencher: triethanolamine | 0.002 | g |
| Solvent: propylene glycol monomethyl ether acetate | 18 | g |

Then, as shown in FIG. 4D, pattern exposure is carried out by irradiating the resist film 302 with exposing light 303 of KrF excimer laser with NA of 0.68 through a mask 304.

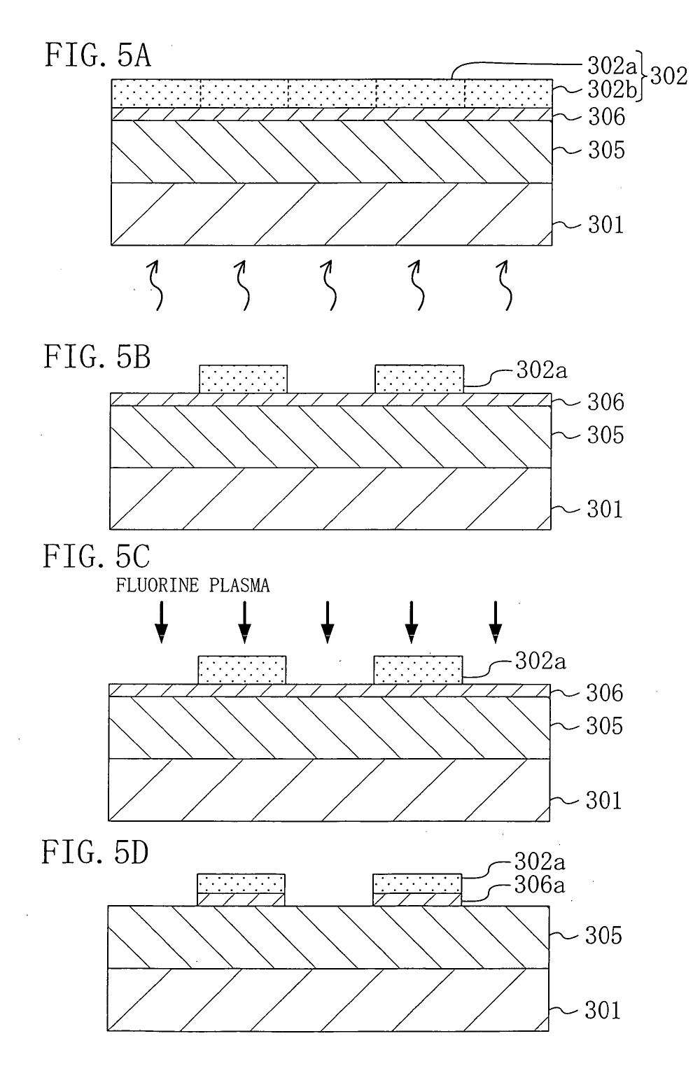

After the pattern exposure, as shown in FIG. 5A, the resist film 302 is baked with a hot plate at a temperature of 110° C. for 60 seconds (post exposure bake).

Next, the resultant resist film 302 is developed with a 2.38 wt % tetramethylammonium hydroxide aqueous solution (alkaline developer). In this manner, a resist pattern 302a made of an unexposed portion of the resist film 302 and having a line width of 0.13 μm is formed in a good shape as shown in FIG. 5B.

Subsequently, as shown in FIG. 5C, the inorganic film 306 is etched by using fluorine plasma with the resist pattern 302a used as a mask, so as to obtain an inorganic film pattern 306a made of the inorganic film 306.

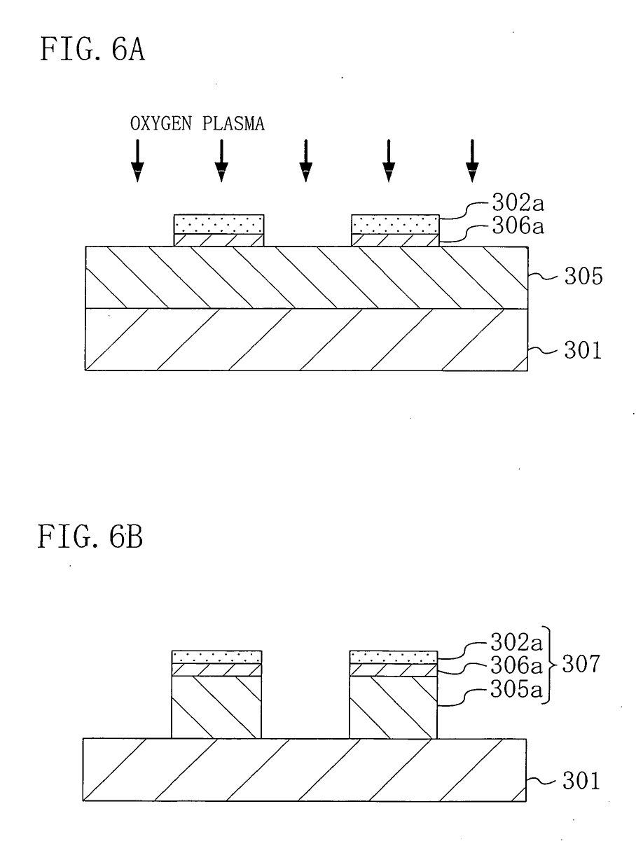

Next, as shown in FIG. 6A, the organic film 305 is etched by using oxygen plasma with the resist pattern 302a and the inorganic film pattern 306a used as a mask, so as to obtain a multilayered pattern 307 with a line width of 0.13 μm having a three-layered structure in a good shape composed of the resist pattern 302a, the inorganic film pattern 306a and an organic film pattern 305a below.

In this manner, according to Embodiment 3, in the resist film 302 including titanium oxide, the titanium oxide included in an exposed portion 302b becomes hydrophilic in the exposure shown in FIG. 4D, and hence, the exposed portion 302b, which attains a hydrophilic property through a photoreaction of the acid generator, becomes more hydrophilic. On the contrary, the unexposed portion of the resist film 302 keeps its hydrophobic property. Therefore, in the development shown in FIG. 5B, a dissolution contrast, that is, a difference in the dissolution rate between the exposed portion 302b and the unexposed portion, is increased. As a result, the resolution of the resist film 302 is improved, so that the resist pattern 302a can be formed in a good shape.

Furthermore, in the dry etching using oxygen plasma shown in FIG. 6A, the resist pattern 302a exhibits sufficient etch resistance owing to the titanium oxide included therein. In addition, the inorganic film 306 with high oxygen plasma resistance is disposed between the resist pattern 302a and the organic film 305, and hence, the resist pattern 302a formed in a good shape can be reinforced against the oxygen plasma. Thus, the resultant multilayered pattern 307 can be definitely formed in a good shape.

It is noted that the organic film 305 is not limited to a hard baked resist film but may be made of hydrocarbon, carbon or the like.

Furthermore, the inorganic film 306 is not limited to a silicon oxide nitride film but may be made of any material appropriately usable in the semiconductor fabrication process such as silicon oxide or silicon nitride.

Although the KrF excimer laser is used as the exposing light in each of Embodiments 1 through 3, which does not limit the invention, and the exposing light may be i-line of a mercury lamp, ArF excimer laser, F₂ laser, ArKr laser, Ar₂ laser, light of a wavelength not shorter than 1 nm and not longer than 30 nm, such as extreme UV, or an electron beam.

Moreover, a positive chemically amplified resist is used in each embodiment, which does not limit the invention, and the present invention is applicable also to a negative chemically amplified resist.

As described so far, according to the resist material and the pattern formation method using the same of this invention, the resolution of a resist film is improved so as to effectively form a fine pattern in a good shape. Accordingly, the present invention is useful as a pattern formation method to be employed in fabrication process or the like for semiconductor devices.

1. A resist material comprising titanium oxide.

2. A pattern formation method comprising the steps of:
forming a resist film including titanium oxide on a substrate;
performing pattern exposure by selectively irradiating said resist film with light of a wavelength of 400 nm or less or an electron beam; and
forming a resist pattern made of said resist film by developing said resist film after the pattern exposure.

3. The pattern formation method of claim 2,
wherein said resist film is made of a chemically amplified resist.

4. The pattern formation method of claim 2,
wherein said light of a wavelength of 400 nm or less is i-line, KrF excimer laser, ArF excimer laser, F₂ laser, ArKr laser, Ar₂ laser or extreme UV of a wavelength not shorter than 1 nm and not longer than 30 nm.

5. A pattern formation method comprising the steps of:
forming an organic film on a substrate;
forming a first resist film including titanium oxide on said organic film;
performing pattern exposure by selectively irradiating said first resist film with light of a wavelength of 400 nm or less or an electron beam;
forming a resist pattern made of said first resist film by developing said first resist film after the pattern exposure; and
forming a pattern by etching said organic film with said resist pattern used as a mask.

6. The pattern formation method of claim 5, further comprising, between the step of forming an organic film and the step of forming a first resist film, a step of forming an inorganic film on said organic film,
wherein said pattern is formed by etching said inorganic film and said organic film with said resist pattern used as a mask in the step of forming a pattern.

7. The pattern formation method of claim 6,
wherein said inorganic film is made of silicon oxide, silicon nitride or silicon oxide nitride.

8. The pattern formation method of claim 5,
wherein said first resist film is made of a chemically amplified resist.

9. The pattern formation method of claim 5,
wherein a second resist film is formed on said substrate and said second resist film is subjected to hard bake in the step of forming an organic film.

10. The pattern formation method of claim 9,
wherein the hard bake is performed at a temperature of 200° C. or more.

11. The pattern formation method of claim 5,
wherein said light of a wavelength of 400 nm or less is i-line, KrF excimer laser, ArF excimer laser, F₂ laser, ArKr laser, Ar₂ laser or extreme UV of a wavelength not shorter than 1 nm and not longer than 30 nm.
